(19) United States
(12) Patent Application Publication
(10) Pub. No.: US 2011/0203514 A1
(43) Pub. Date: Aug. 25, 2011

(54) NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS

(75) Inventors: Siddha Pimputkar, Goleta, CA (US); Derrick S. Kamber, Goleta, CA (US); James S. Speck, Goleta, CA (US); Shuji Nakamura, Santa Barbara, CA (US)

(73) Assignee: THE REGENTS OF THE UNIVERSITY OF CALIFORNIA, Oakland, CA (US)

(21) Appl. No.: 13/128,088

(22) PCT Filed: Nov. 4, 2009
(86) PCT No.: PCT/US2009/063238

§ 371 Date: May 6, 2011

Related U.S. Application Data
(60) Provisional application No. 61/112,552, filed on Nov. 7, 2008.

(51) Int. Cl. C30B 19/10

(52) U.S. Cl. 117/64; 117/206

(57) ABSTRACT

Reactor designs for use in ammonothermal growth of group-III nitride crystals envision a different relative placement of source materials and seed crystals with respect to each other, and with respect to the vessel containing a solvent. This placement results in a difference in fluid dynamical flow patterns within the vessel.

### CROSS REFERENCE TO RELATED APPLICATIONS

This application claims the benefit under 35 U.S.C. Section 119(e) of the following co-pending and commonly-assigned application:

U.S. Provisional Application Ser. No. 61/112,552, filed on Nov. 7, 2008, by Siddha Pimputkar, Derrick S. Kamber, James S. Speck and Shuji Nakamura, entitled “NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS,” attorney's docket number 30794.297-US-P1 (2009-284-1);

which application is incorporated by reference herein.

This application is related to the following co-pending and commonly-assigned U.S. patent applications:

U.S. Utility patent application Ser. No. 11/921,396, filed on Nov. 30, 2007, by Kenji Fujito, Tadao Hashimoto and Shuji Nakamura, entitled “METHOD FOR GROWING GROUP-III NITRIDE CRYSTALS IN SUPERCRITICAL AMMONIA USING AN AUTOCLAVE,” attorneys docket number 30794.129-US-WO (2005-339-2), which application claims the benefit under 35 U.S.C. Section 365(c) of PCT Utility Patent Application Serial No. US2005/024239, filed on Jul. 8, 2005, by Kenji Fujito, Tadao Hashimoto and Shuji Nakamura, entitled “METHOD FOR GROWING GROUP III-NITRIDE CRYSTALS IN SUPERCRITICAL AMMONIA USING AN AUTOCLAVE,” attorneys' docket number 30794.129-WO-01 (2005-339-1);

U.S. Utility patent application Ser. No. 11/784,339, filed on Apr. 6, 2007, by Tadao Hashimoto, Makoto Saito, and Shuji Nakamura, entitled “METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-U1 (2006-204), which application claims the benefit under 35 U.S.C. Section 119(e) of U.S. Provisional Patent Application Ser. No. 60/790,310, filed on Apr. 7, 2006, by Tadao Hashimoto, Makoto Saito, and Shuji Nakamura, entitled “A METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-P1 (2006-204);

U.S. Utility patent application Ser. No. 11/765,629, filed on Jun. 20, 2007, by Tadao Hashimoto, Hitoshi Sato and Shuji Nakamura, entitled “OPTO-ELECTRONIC AND ELECTRONIC DEVICES USING N-FACE OR M-PLANE GaN SUBSTRATE PREPARED WITH AMMONOTHERMAL GROWTH,” attorneys' docket number 30794.184-US-U1 (2006-666), which application claims the benefit under 35 U.S.C. Section 119(e) of U.S. Provisional Application Ser. No. 60/815,507, filed on Jun. 21, 2006, by Tadao Hashimoto, Hitoshi Sato, and Shuji Nakamura, entitled “OPTO-ELECTRONIC AND ELECTRONIC DEVICES USING N-FACE GaN SUBSTRATE PREPARED WITH AMMONOTHERMAL GROWTH,” attorneys' docket number 30794.184-US-P1 (2006-666);

U.S. Utility patent Ser. No. 12/234,244, filed on Sep. 19, 2008, by Tadao Hashimoto and Shuji Nakamura, entitled “GALLIUM NITRIDE BULK CRYSTALS AND THEIR GROWTH METHOD,” attorneys' docket number 30794.244-US-U1 (2007-809), which application claims the benefit under 35 U.S.C. Section 119(e) of U.S. Provisional Patent Application Ser. No. 60/973,662, filed on Sep. 19, 2007, by Tadao Hashimoto and Shuji Nakamura, entitled “GALLIUM NITRIDE BULK CRYSTALS AND THEIR GROWTH METHOD,” attorneys' docket number 30794.244-US-P1 (2007-809-1);

U.S. Utility patent application Ser. No. 11/977,661, filed on Oct. 25, 2007, by Tadao Hashimoto, entitled “METHOD FOR GROWING GROUP III-NITRIDE CRYSTALS IN A MIXTURE OF SUPERCRITICAL AMMONIA AND NITROGEN, AND GROUP III-NITRIDE CRYSTALS GROWN THEREBY,” attorneys' docket number 30794.253-US-U1 (2007-774-2), which application claims the benefit under 35 U.S.C. Section 119(e) of U.S. Provisional Application Ser. No. 60/854,567, filed on Oct. 25, 2006, by Tadao Hashimoto, entitled “METHOD FOR GROWING GROUP-III NITRIDE CRYSTALS IN MIXTURE OF SUPERCRITICAL AMMONIA AND NITROGEN AND GROUP-III NITRIDE CRYSTALS,” attorneys' docket number 30794.253-US-P1 (2007-774);

U.S. Utility patent application Ser. No. ______, filed on same date herewith, by Siddha Pimputkar, Derrick S. Kamber, Makoto Saito, Steven P. DenBaars, James S. Speck and Shuji Nakamura, entitled “GROUP-III NITRIDE MONOCRYSTAL WITH IMPROVED CRYSTAL QUALITY GROWN ON AN ETCHED-BACK SEED CRYSTAL AND METHOD OF PRODUCING THE SAME,” attorneys' docket number 30794.288-US-U1 (2009-154-2), which application claims the benefit under 35 U.S.C. Section 119(e) of U.S. Provisional Application Ser. No. 61/111,644, filed on Nov. 5, 2008, by Siddha Pimputkar, Derrick S. Kamber, Makoto Saito, Steven P. DenBaars, James S. Speck and Shuji Nakamura, entitled “GROUP-III NITRIDE MONOCRYSTAL WITH IMPROVED CRYSTAL QUALITY GROWN ON AN ETCHED-BACK SEED CRYSTAL AND METHOD OF PRODUCING THE SAME,” attorney's docket number 30794.288-US-P1 (2009-154-1);

P.C.T. International Patent Application Serial No. PCT/US09/xxxxx, filed on same date herewith, by Derrick S. Kamber, Siddha Pimputkar, Makoto Saito, Steven P. DenBaars, James S. Speck and Shuji Nakamura, entitled “GROUP-III NITRIDE MONOCRYSTAL WITH IMPROVED PURITY AND METHOD OF PRODUCING THE SAME,” attorneys' docket number 30794.295-WO-U1 (2009-282-2), which application claims the benefit under 35 U.S.C. Section 119(e) of U.S. Provisional Application Ser. No. 61/112,555, filed on Nov. 7, 2008, by Derrick S. Kamber, Siddha Pimputkar, Makoto Saito, Steven P. DenBaars, James S. Speck and Shuji Nakamura, entitled “GROUP-III NITRIDE MONOCRYSTAL WITH IMPROVED PURITY AND METHOD OF PRODUCING THE SAME,” attorney's docket number 30794.295-US-P1 (2009-282-1);

P.C.T. International Patent Application Serial No. PCT/US09/xxxxx, filed on same date herewith, by Siddha Pimputkar, Derrick S. Kamber, James S. Speck and Shuji Nakamura, entitled “REACTOR DESIGNS FOR USE IN AMMONOTHERMAL GROWTH OF GROUP-III NITRIDE CRYSTALS,” attorneys' docket number 30794.296-WO-U1 (2009-283/285-2), which application claims the benefit under 35 U.S.C. Section 119(e) of U.S. Provisional Application Ser. No. 61/112,560, filed on Nov. 7, 2008, by Siddha Pimputkar, Derrick S. Kamber, James S. Speck and Shuji Nakamura, entitled “REACTOR DESIGNS FOR USE IN AMMONOTHERMAL GROWTH OF GROUP-III NITRIDE CRYSTALS,” attorney's docket number 30794.296-US-P1 (2009-283/285-1);

P.C.T. International Patent Application Serial No. PCT/US09/xxxxx, filed on same date herewith, by Siddha Pimputkar, Derrick S. Kamber, James S. Speck and Shuji Nakamura, entitled “ADDITION OF HYDROGEN AND/OR NITROGEN CONTAINING COMPOUNDS TO THE NITROGEN-CONTAINING SOLVENT USED DURING THE AMMONOTHERMAL GROWTH OF GROUP-III NITRIDE CRYSTALS,” attorneys' docket number 30794.298-WO-U1 (2009-286-2), which application claims the benefit under 35 U.S.C. Section 119(e) of U.S. Provisional Application Ser. No. 61/112,558, filed on Nov. 7, 2008, by Siddha Pimputkar, Derrick S. Kamber, James S. Speck and Shuji Nakamura, entitled “ADDITION OF HYDROGEN AND/OR NITROGEN CONTAINING COMPOUNDS TO THE NITROGEN-CONTAINING SOLVENT USED DURING THE AMMONOTHERMAL GROWTH OF GROUP-III NITRIDE CRYSTALS TO OFFSET THE DECOMPOSITION OF THE NITROGEN-CONTAINING SOLVENT AND/OR MASS LOSS DUE TO DIFFUSION OF HYDROGEN OUT OF THE CLOSED VESSEL,” attorney's docket number 30794.298-US-P1 (2009-286-1);

P.C.T. International Patent Application Serial No. PCT/US09/xxxxx, filed on same date herewith, by Siddha Pimputkar, Derrick S. Kamber, James S. Speck and Shuji Nakamura, entitled “CONTROLLING RELATIVE GROWTH RATES OF DIFERENT EXPOSED CRYSTALLOGRAPHIC FACETS OF A GROUP-III NITRIDE CRYSTAL DURING THE AMMONOTHERMAL GROWTH OF A GROUP-III NITRIDE CRYSTAL,” attorneys' docket number 30794.299-WO-U1 (2009-287-2), which application claims the benefit under 35 U.S.C. Section 119(e) of U.S. Provisional Application Ser. No. 61/112,545, filed on Nov. 7, 2008, by Siddha Pimputkar, Derrick S. Kamber, James S. Speck and Shuji Nakamura, entitled “CONTROLLING RELATIVE GROWTH RATES OF DIFERENT EXPOSED CRYSTALLOGRAPHIC FACETS OF A GROUP-III NITRIDE CRYSTAL DURING THE AMMONOTHERMAL GROWTH OF A GROUP-III NITRIDE CRYSTAL,” attorney's docket number 30794.299-US-P1 (2009-287-1); and

P.C.T. International Patent Application Serial No. PCT/US09/xxxxx, filed on same date herewith, by Siddha Pimputkar, Derrick S. Kamber, James S. Speck and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorneys' docket number 30794.300-WO-U1 (2009-288-2), which application claims the benefit under 35 U.S.C. Section 119(e) of U.S. Provisional Application Ser. No. 61/112,550, filed on Nov. 7, 2008, by Siddha Pimputkar, Derrick S. Kamber, James S. Speck and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorney's docket number 30794.300-US-P1 (2009-288-1); all of which applications are incorporated by reference herein.

### BACKGROUND OF THE INVENTION

1. Field of the Invention

This invention relates to ammonothermal growth of group-III nitrides.

2. Description of the Related Art

Ammonothermal growth of group-III nitrides, for example, GaN, involves placing, within a reactor vessel, group-III containing source materials, group-III nitride seed crystals, and a nitrogen-containing solvent, such as ammonia, sealing the vessel and heating the vessel to conditions such that the vessel is at elevated temperatures (between 23° C. and 1000° C.) and high pressures (between 1 atm and, for example, 30,000 atm). Under these temperatures and pressures, the solvent may become a supercritical fluid which normally exhibits enhanced solubility of the source materials into solution. The solubility of the source materials into the solvent is dependent on the temperature, pressure and density of the solvent, among other things. By creating two different zones within the vessel, it is possible to establish a solubility gradient where, in one zone, the solubility will be higher than in a second zone. The source materials are then preferentially placed in the higher solubility zone and the seed crystals in the lower solubility zone. By establishing fluid motion of the solvent with the dissolved source materials between these two zones, for example, by making use of natural convection, it is possible to transport the dissolved source materials from the higher solubility zone to the lower solubility zone where the dissolved source materials are deposited onto the seed crystals to grow the group-III nitride crystals.

The current state of the art uses a device or vessel that is heated to raise the entire vessel contents to elevated temperatures and pressures. The heating of the vessel is commonly performed by heating the outer walls of the vessel and, by virtue of heat transfer, heating the inner walls of the vessel, which, in turn, heats the solvent, source materials, seed crystals and other material present within the vessel.

One of the features of current ammonothermal reactor vessels is that, due to the vessel design and baffles used, the fluids within the vessel are heavily restricted in their motion and may “slush” when transported between upper and lower zones in the vessel. This slushing effect may be irregular and hard to control, leading potentially to lower growth rates and poorer crystal quality.

Thus, what is needed in the art are new reactor vessel designs for use in ammonothermal growth of group-III nitride crystals. Specifically, what is needed in the art are improved techniques for controlling fluid motion in reactor vessels used in ammonothermal growth of group-III nitride crystals. In addition, what is needed in the art are improved baffle designs for reactor vessels used in ammonothermal growth of group-III nitride crystals. The present invention satisfies these needs.

### SUMMARY OF THE INVENTION

To overcome the limitations in the prior art described above, and to overcome other limitations that will become apparent upon reading and understanding the present invention, the present invention discloses improved reactor vessel designs for use in ammonothermal growth of group-III nitride crystals. Specifically, these reactor designs envision a different relative placement of source materials and seed crystals with respect to each other, and with respect to the vessel containing a solvent. This placement results in a difference in fluid dynamical flow patterns within the vessel.

### BRIEF DESCRIPTION OF THE DRAWINGS

Referring now to the drawings in which like reference numbers represent corresponding parts throughout:

FIG. 1 is a schematic of a high-pressure vessel according to an embodiment of the present invention.

FIG. 2 is a flowchart illustrating the method according to an embodiment of the present invention.

FIG. 3 illustrates one possible embodiment of a reactor vessel used in an embodiment of the present invention.

FIG. 4 illustrates another possible embodiment of a reactor vessel used in an embodiment of the present invention.

### DETAILED DESCRIPTION OF THE INVENTION

In the following description of the preferred embodiment, reference is made to a specific embodiment in which the invention may be practiced. It is to be understood that other embodiments may be utilized and structural changes may be made without departing from the scope of the present invention.

Apparatus Description

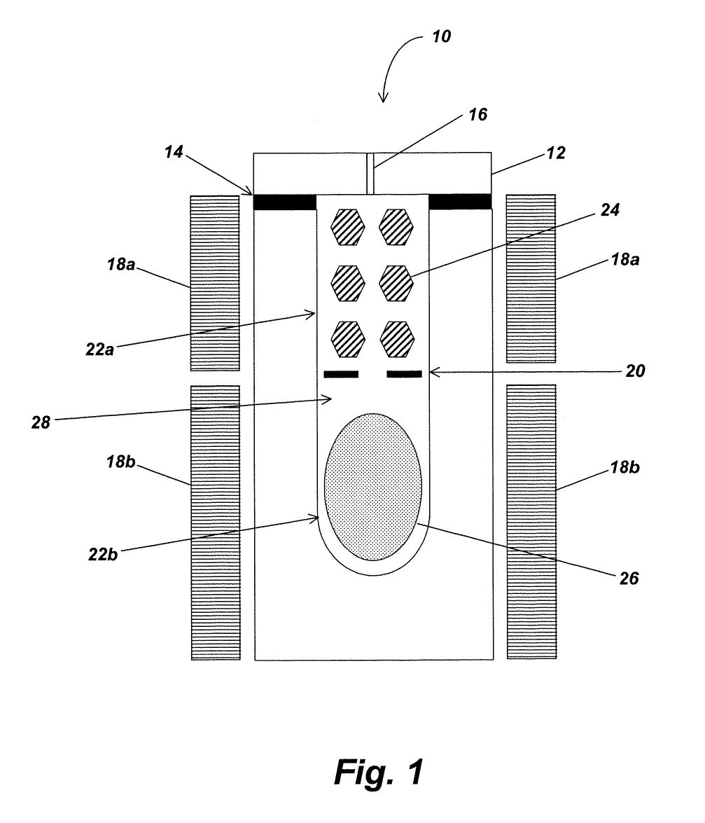

FIG. 1 is a schematic of an ammonothermal growth system comprising a high-pressure reaction vessel 10 according to one embodiment of the present invention. The vessel, which is an autoclave, may include a lid 12, gasket 14, inlet and outlet port 16, and external heaters/coolers 18a and 18b. A baffle plate 20 divides the interior of the vessel 10 into two zones 22a and 22b, wherein the zones 22a and 22b are separately heated and/or cooled by the external heaters/coolers 18a and 18b, respectively. An upper zone 22a may contain one or more group-III nitride seed crystals 24 and a lower zone 22b may contain one or more group-III containing source materials 26, although these positions may be reversed in other embodiments. Both the group-III nitride seed crystals 24 and group-III containing source materials 26 may be contained within baskets or other containment devices, which are typically comprised of an Ni—Cr alloy. The vessel 10 and lid 12, as well as other components, may also be made of a Ni—Cr based alloy. Finally, the interior of the vessel 10 is filled with a nitrogen-containing solvent 28 to accomplish the ammonothermal growth.

Process Description

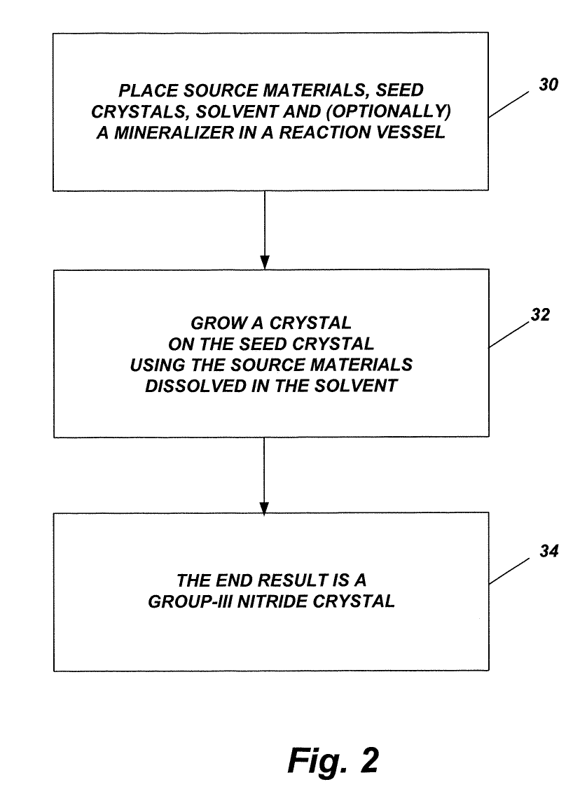

FIG. 2 is a flow chart illustrating a method for obtaining or growing a group-III nitride-containing crystal using the apparatus of FIG. 1 according to one embodiment of the present invention.

Block 30 represents placing one or more group-III nitride seed crystals 24, one or more group-III containing source materials 26, and a nitrogen-containing solvent 28 in the vessel 10, wherein the seed crystals 24 are placed in a seed crystals zone (i.e., either 22a or 22b, namely the opposite of the zone 22b or 22a containing the source materials 26), the source materials 26 are placed in a source materials zone (i.e., either 22b or 22a, namely the opposite of the zone 22a or 22b containing the seed crystals 24). The seed crystals 24 comprise a group-III containing crystal; the source materials 26 comprise a group-III containing compound, a group-III element in its pure elemental form, or a mixture thereof, i.e., a group-III nitride monocrystal, a group-III nitride polycrystal, a group-III nitride powder, group-III nitride granules, or other group-III containing compound; and the solvent 28 is supercritical ammonia or one or more of its derivatives. An optional mineralizer may be placed in the vessel 10 as well, wherein the mineralizer increases the solubility of the source materials 26 in the solvent 28 as compared to the solvent 28 without the mineralizer.

Block 32 represents growing group-III nitride crystals on one or more surfaces of the seed crystals 24, wherein the conditions for growth include forming a temperature gradient between the seed crystals 24 and the source materials 26 that causes a higher solubility of the source materials 26 in the source materials zone and a lower solubility, as compared to the higher solubility, of the source materials 26 in the seed crystals zone. Specifically, growing the group-III nitride crystals on one or more surfaces of the seed crystal 24 occurs by changing the source materials zone temperatures and the seed crystals zone temperatures to create a temperature gradient between the source materials zone and the seed crystals zone that produces a higher solubility of the source materials 26 in the solvent 28 in the source materials zone as compared to the seed crystals zone. For example, the source materials zone and seed crystals zone temperatures may range between 0° C. and 1000° C., and the temperature gradients may range between 0° C. and 1000° C.

Block 34 comprises the resulting product created by the process, namely, a group-III nitride crystal grown by the method described above. A group-III nitride substrate may be created from the group-III nitride crystal, and a device may be created using the group-III nitride substrate.

Reactor Designs for Controlling Fluid Motion

The present invention envisions various different relative placements of the seed crystals 24 and the source materials 26 with respect to each other, and with respect to the vessel 10 containing the solvent 28. This placement results in a difference in fluid dynamical flow patterns of the solvent 28 within the vessel 10.

One possible example of this invention, although it should not be considered limiting in any way, is illustrated in FIG. 1, where the external heaters/coolers 18a and 18b could be combined with one or more internal heaters/coolers inside the vessel 10. These heaters/coolers would create the zones 22a and 22b within the vessel 10 that are at different temperatures.

Generally speaking, the density of a fluid may decrease with increased temperature. Therefore, a fluid comprised of the solvent 28 with the dissolved source materials 26 at a higher temperature will have a lower density than the same fluid at a lower temperature. Further, based on buoyancy forces, lower density material will try to place itself above the higher density material. Therefore, if one would place a lower density (higher temperature) zone 22a vertically below a higher density (lower temperature) zone 22b, the fluid will try to move from the lower zone 22b to the upper zone 22a, and from the top to the bottom. This fluid motion motivated by buoyancy forces may be called convective flow.

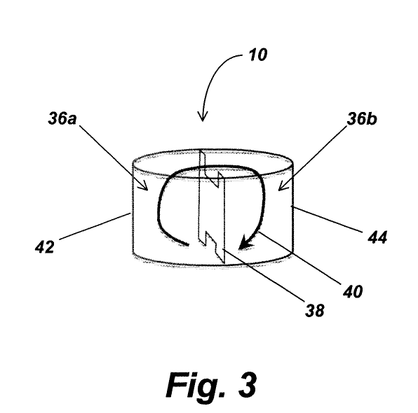

FIG. 3 illustrates another embodiment of the present invention, which entails arranging the relative positions of the seed crystals 24 and the source materials 28 horizontally with respect to each other by dividing the vessel 10 into at least first and second zones 36a and 36b by one or more substantially vertically positioned separators 38, i.e., baffle plates, that separate the first and second zones 36a and 36b, such that the first zone 36a is substantially horizontally opposed from the second zone 36. The seed crystals 24 are placed in the first zone 36a and the source materials 36 are placed in the second zone 36b, although these positions may be reversed in other embodiments. The vessel 10 is then filled with the solvent 28 for dissolving the source materials 26, wherein a fluid comprised of the solvent 28 with the dissolved source materials 26 is transported to the seed crystals 24 for growth of the crystals 34. Substantially circular fluid motion 40 is created within the vessel 10 by creating conditions within the first zone 36a where the fluid has a lower density and by creating conditions within the second zone 36b where the fluid has a higher density as compared to the lower density, although these conditions may be reversed in other embodiments.

The example of FIG. 3, which should not be seen limiting in any fashion, uses these buoyancy forces in the following manner to set up the illustrated pattern of fluid motion. It is assumed that the fluid comprised of the solvent 28 is initially stationary and isothermal, and the vessel 10 contains at least one substantially vertically positioned baffle plate 38 separating the vessel 10 into substantially horizontally opposed zones 36a and 36b, wherein zones 36a and 36b are positioned on substantially horizontally opposed sides of the vessel 10.

The wall(s) 42 and 44 on these respective substantially horizontally opposed sides of the vessel 10 are then heated and/or cooled to different temperatures, such that the wall(s) 42 on a first side of the vessel 10 are at a higher temperature than the wall(s) 44 on a second side of the vessel 10, which are at a lower temperature as compared to the higher temperature. The solvent 28 in the near vicinity of the walls 42 on the first side will heat up over time, causing it to preferentially rise within the vessel 10 due to its decreasing density. On the other hand, the solvent 28 in the near vicinity of the walls 44 on the second side of the vessel 10 will preferentially be cooler over time as compared to the heated solvent 28 and hence will have a higher density than the heated solvent 28, causing it to preferentially drop within the vessel 10 due to its increasing density. The combination of fluid rising on the first side of the vessel 10 and dropping on the second side of the vessel 10 may result in substantially circular motion of the fluid within the vessel 10, as shown by the arrow 40 in FIG. 3.

In addition, this circular fluid motion may be further enhanced by providing one or more openings in the baffle plate 38 that allow for the displaced fluid to move between the first and second zones 36a and 36b, i.e., from one zone 36a, 36b to another zone 36b, 36a in the vessel 10. For example, the lower density, hotter fluid will rise in the first side of the vessel 10. The fluid above it may try to move out of the way and, by doing so, will either mix with the rising fluid or move to the second side of the vessel 10 through the opening in the baffle plate 38. A similar scenario holds true for the higher density, cooler fluid on the second side of the vessel 10, where the falling fluid displaces the fluid directly below it and may displace it to the first side of the vessel 10, in addition to possibly mixing with the falling fluid. Therefore, by both convective flow and displacement of fluids from one side of the vessel 10 to the other, circular motion 40 of the fluid is both established and maintained. In order to optimize fluid motion, it may become necessary to change the temperature gradient, absolute temperatures across the two zones 36a, 36b, and/or the size of the baffle plate 38 openings.

This vessel 10 design has the benefit of improved fluid dynamics, such as the enhanced and relatively unrestricted circular motion of the fluid, and enhanced mass transport of the source materials 26 from the source materials zone to the seed crystals zone of the vessel 10. The enhanced mass transport may lead to enhanced growth rates and better crystal quality for the group-III nitride crystal 34.

While not shown in FIG. 1 or 3, this invention also envisions the possible use of other devices to restrict fluid motion, such as additional baffle plates, which may be placed anywhere in any particular direction within the vessel 10 and have a variety of shapes, forms or sizes.

Note that, while FIG. 3 shows only two zones 36a and 36b in the vessel 10, alternative embodiment may have more than two zones 36a and 36b. Specifically, it is anticipated that the vessel 10 may be subdivided into any number of differently positioned zones.

Further, while it has been mentioned in this invention that substantially vertically positioned baffles 38 may be used to separate the vessel 10 volume into zones 36a and 36b, it is important to emphasize that these substantially vertically positioned baffles 38 do not need to be perfectly vertically aligned with respect to the vessel 10, but may be placed at an angle within the vessel 10 to additionally control the fluid dynamical flow of the fluid and the heat transfer, thereby indirectly controlling the solubility zones 36a and 36b within the vessel 10. One simple example of this would be to have the lower part of the baffle 38 touching the lower left rim of the cylindrical shaped vessel 10 and the upper part of the baffle 38 touching the upper right rim of the cylindrical shaped vessel 10 (or the reverse), thereby creating zones 36a and 36b comprised of two cylindrical wedges of space within the vessel 10 with varying cross-sectional areas.

Also, while FIG. 3 portrays the vessel 10 to be wider than tall, this is not limiting in any sense. It is possible to envision using existing longer ammonothermal vessels 10 without any modification, but dividing the vessel 10 into at least two substantially horizontally opposed and substantially vertically separated zones 36a and 36b in addition to any other separations, such as two substantially vertically opposed and substantially horizontally separated zones. In addition, the zones 36a and 36b may encompass similar volumes within the vessel 10, but do not need to. As noted above, more than two zones 36a and 36b may be implemented to achieve more sophisticated and enhanced fluid motion.

Further, the placement of the seed crystals 24 and source materials 26 within the vessel 10 and with respect to the zones 36a and 36b within the vessel 10 is under no restrictions or limitations. They may be placed only within a small part of the entire available space of the zone 36a or 36b, or they may be distributed along the entire available space of the zone 36a or 36b. One such example may include placing the source materials 26 in the lower left portion of zone 36a and the seed crystals 24 in the upper right portion of zone 36b. The benefits of this particular placement would be areas in which the solvent 28 would be able to either heat up or cool down by virtue of heat transfer to and from the vessel 10 and/or to and from heaters and/or coolers, possibly placed externally from or internally to the vessel 10, and thereby changing its ability to dissolve and retain the source materials 26.

An alternative example may include placing the source materials 26 in the upper left portion of zone 36a and the seed crystals 24 in the lower right portion of zone 36b. Another alternative would entail reversing the placements of the source materials 26 in zone 36b and the seed crystals 24 in zone 36a, as well as the placements in the portions of these zones 36a and 36b.

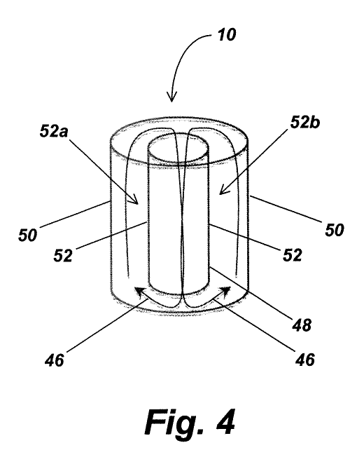

Other possible embodiments of these substantially horizontally opposed zones and the placement therein of the source materials 26 with respect to the seed crystals 24, are illustrated in FIG. 4, where the circular motion of the fluid indicated by arrows 46 within the vessel 10 is further modified to a torus-like shaped fluid flow by means of substantially cylindrically shaped baffle 48, higher temperature surfaces 50, and lower temperature surfaces 52, and may be performed in either direction (clockwise or counter-clockwise). This results in separate zones 54a and 54b for the placement of the seed crystals 24 with respect to the source materials 26, respectively, although a reverse placement may be used as well.

The vessel 10 designs envisioned in this invention may benefit from internal heaters and/or cooling devices placed inside, outside, along the baffles and vessel 10 walls to further enhance solubility gradients and fluid motion. The methods used to establish the fluid motion may be of any nature or device, but it may be advantageous to use heaters and/or cooling mechanisms and the differences in temperatures and hence densities to make use of natural convective flows.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for growing crystals, comprising:
(a) providing a vessel for containing source materials and seed crystals,
(b) dividing the vessel into at least first and second zones, such that the first zone is substantially horizontally opposed from the second zone;
(c) placing the seed crystals in the first zone and placing the source materials in the second zone; and
(d) filling the vessel with a solvent for dissolving the source materials, wherein a fluid comprised of the solvent with the dissolved source materials is transported to the seed crystals for growth of the crystals;
(f) wherein substantially circular fluid motion is created within the vessel by creating conditions within the first zone where the fluid has a lower density and by creating conditions within the second zone where the fluid has a higher density as compared to the lower density.

2. The method of claim 1, wherein the source materials comprise group-III containing source materials, the seed crystals comprise group-III nitride seed crystals, the solvent comprises a nitrogen-containing solvent, and the crystals comprise group-III nitride crystals.

3. The method of claim 1, wherein the first and second zones are defined by different temperatures, such that the first zone contains the fluid at a higher temperature and the second zone contains the fluid at a lower temperature as compared to the higher temperature.

4. The method of claim 1, wherein the vessel is divided into the first and second zones by one or more substantially vertically positioned separators that separate the first and second zones.

5. The method of claim 4, wherein the separator is a baffle plate.

6. The method of claim 5, wherein the fluid motion is enhanced by providing openings in the baffle plate that allow the fluid to move between the first and second zones.

7. The method of claim 4, wherein the separator is a substantially cylindrically shaped baffle.

8. The method of claim 7, wherein the substantially circular fluid motion comprises a torus-like shaped fluid flow.

9. An apparatus for growing crystals, comprising:
(a) a vessel for containing source materials and seed crystals,
(b) the vessel being divided into at least first and second zones, such that the first zone is substantially horizontally opposed from the second zone;
(c) the seed crystals being placed in the first zone and the source materials being placed in the second zone; and
(d) the vessel being filled with a solvent for dissolving the source materials, wherein a fluid comprised of the solvent with the dissolved source materials is transported to the seed crystals for growth of the crystals;
(f) wherein substantially circular fluid motion is created within the vessel by creating conditions within the first zone where the fluid has a lower density and by creating conditions within the second zone where the fluid has a higher density as compared to the lower density.

10. The apparatus of claim 9, wherein the source materials comprise group-III containing source materials, the seed crystals comprise group-III nitride seed crystals, the solvent comprises a nitrogen-containing solvent, and the crystals comprise group-III nitride crystals.

11. The apparatus of claim 9, wherein the first and second zones are defined by different temperatures, such that the first zone contains the fluid at a higher temperature and the second zone contains the fluid at a lower temperature as compared to the higher temperature.

12. The apparatus of claim 9, wherein the vessel is divided into the first and second zones by one or more substantially vertically positioned separators that separate the first and second zones.

13. The apparatus of claim 12, wherein the separator is a baffle plate.

14. The apparatus of claim 13, wherein the fluid motion is enhanced by providing openings in the baffle plate that allow the fluid to move between the first and second zones.

15. The apparatus of claim 12, wherein the separator is a substantially cylindrically shaped baffle.

16. The apparatus of claim 15, wherein the substantially circular fluid motion comprises a torus-like shaped fluid flow.
